(19) United States
(12) Patent Application Publication
(10) Pub. No.: US 2017/0278998 A1
(43) Pub. Date: Sep. 28, 2017

(54) MANUFACTURING METHOD FOR SOLAR CELL AND SOLAR CELL

(71) Applicant: MITSUBISHI ELECTRIC CORPORATION, Chiyoda-ku, Tokyo (JP)

(72) Inventors: Hiroya YAMARIN, Tokyo (JP); Yusuke SHIRAYANAGI, Tokyo (JP)

(73) Assignee: MITSUBISHI ELECTRIC CORPORATION, Chiyoda-ku, Tokyo (JP)

(21) Appl. No.: 15/122,725

(22) PCT Filed: Mar. 4, 2015
(86) PCT No.: PCT/JP2015/056405

§ 371 Date: Aug. 31, 2016

(30) Foreign Application Priority Data
Mar. 5, 2014 (JP) 2014-043228

(51) Int. Cl. H01L 31/061; H01L 31/0216; H01L 31/18; H01L 31/0236; H01L 31/028; H01L 31/0288; H01L 31/02; H01L 31/0224

(52) U.S. Cl. CPC H01L 31/061; H01L 31/0201; H01L 31/02167; H01L 31/022433; H01L 31/02363; H01L 31/028; H01L 31/0288; H01L 31/1804; H01L 31/1864; H01L 31/1868

(57) ABSTRACT

A manufacturing method for a solar cell includes a step of forming a p-type diffusion layer on one principal surface side of an n-type silicon substrate and forming an n-type silicon substrate having a pn junction, a step of forming a laminated film of a silicon oxide film and a silicon nitride film as a passivation film on a surface on a side of a light receiving surface that is an n type, a step of forming an open region in the passivation film, a step of diffusing n-type impurities with respect to the open region of the passivation film by using the passivation film as a mask to form a high-concentration diffusion region, and a step of forming a metal electrode selectively in the high-concentration diffusion region that is exposed in the open region of the passivation film.

### FIELD

The present invention relates to a manufacturing method for a solar cell and a solar cell.

### BACKGROUND

Conventionally, in a crystalline solar cell in which a second conductivity-type diffusion layer is formed on a surface of a first conductivity-type semiconductor substrate such as a monocrystalline silicon substrate, a selective emitter structure is often used in order to increase the incident photoelectric conversion efficiency. The selective emitter structure is a structure in which an emitter region selectively having a higher surface impurity concentration than that of a peripheral area is formed in a region connected to an electrode, in a diffusion layer formed on a surface of a semiconductor substrate. By forming the selective emitter structure, ohmic contact resistance between the semiconductor substrate and the electrode decreases, thereby improving a fill factor. Further, in the emitter region, because the impurities are diffused in a high concentration, the field effect increases in a region connected to the electrode and recombination of carriers can be suppressed, thereby improving an open circuit voltage.

For example, Patent Literature 1 discloses a method for selectively forming a high-concentration impurity diffusion layer by using a doping paste in a back-surface junction-type solar cell.

As a method for connecting a metal electrode to an impurity diffusion region via a passivation film or an antireflection film that is formed on a silicon substrate interface, a method for connecting a metal electrode to an impurity diffusion region by a fire through method using high-temperature heating and burning at a temperature of about 800° C. has been also proposed.

Alternatively, as in Patent Literatures 2 and 3, a method for opening a passivation film by an etching paste and forming a metal electrode in an open region has been also disclosed.

### CITATION LIST

### Patent Literatures

Patent Literature 1: Japanese Patent Application Laid-open No. 2008-186927
Patent Literature 2: Japanese Patent Application Laid-open No. 2013-004831
Patent Literature 3: Japanese Patent Application Laid-open No. 2013-004832

### SUMMARY

### Technical Problem

However, according to the conventional techniques described above, even in Patent Literatures 2 and 3, a selective emitter structure is formed by opening a passivation film by applying an etching paste and further printing a metal electrode thereon, in accordance with the emitter region that is a high-concentration diffusion region having a high impurity concentration. According to this method, it is necessary to take a wide range of the high-concentration diffusion region in order to align a designed mask pattern with the high-concentration diffusion region, the open region by means of the etching paste, and the metal electrode. In the high-concentration diffusion region, a passivation effect in a bonding interface of a minority carrier contributing to power generation can be increased by the field effect. Meanwhile, the carriers generated by sunlight in the impurity diffusion layer recombine in the high-concentration diffusion region and do not contribute to light conversion. Therefore, it is necessary to design the high-concentration diffusion region in the same region as the metal electrode in order to obtain the passivation effect by an electric field on the bonding interface and to decrease the ohmic contact resistance.

Particularly, in order to form a p-type diffusion layer, a high-concentration p⁺ layer can be formed simultaneously with fire through of the passivation film by high-temperature burning, after an Al electrode has been formed. However, in the case where a high-concentration n-type diffusion layer, that is, n⁺ layer is to be formed, it is difficult to diffuse n-type impurities such as phosphorus by burning of the metal electrode. Therefore, it is necessary to employ a method for forming a metal electrode after a high-concentration n⁺ layer is formed by vapor-phase diffusion by diffused phosphorus oxychloride (POCl₃), diffusion by a doping paste containing phosphorus, or diffusion by ion implantation.

The present invention has been achieved in view of the above problems, and an object of the present invention is to provide a solar cell having a high incident photoelectric conversion efficiency that can form an n⁺-type high-concentration diffusion region selectively in a metal electrode forming region.

### Solution to Problem

In order to solve the problems and achieve the object, according to an aspect of the present invention, there is provided a manufacturing method for a solar cell including: a step of forming a second conductivity-type semiconductor region on one principal surface side of a first conductivity-type silicon substrate and forming a silicon substrate having a pn junction; a step of forming a passivation film on a surface of a side of a first principal surface that is an n type, among the first principal surface and second principal surface of the silicon substrate; a step of forming an open region in the passivation film; a step of diffusing n-type impurities with respect to the open region of the passivation film by using the passivation film as a mask to form a high-concentration diffusion region; and a step of forming a collecting electrode selectively in the high-concentration diffusion region that is exposed in the open region of the passivation film.

### Advantageous Effects of Invention

According to the present invention, it is possible to obtain a solar cell having a high incident photoelectric conversion efficiency that can form an n⁺-type high-concentration diffusion region selectively in a metal electrode forming region.

### BRIEF DESCRIPTION OF DRAWINGS

FIGS. 1(a) and 1(b) are diagrams schematically illustrating a solar cell according to a first embodiment, where FIG. 1(a) is a plan view, and FIG. 1(b) is a sectional view along a line A-A′ in FIG. 1(a).

FIGS. 2(a) to (d) are process sectional views illustrating a manufacturing process of the solar cell according to the first embodiment.

FIGS. 3(a) to (d) are process sectional views illustrating a manufacturing process of the solar cell according to the first embodiment.

FIGS. 4(a) to (c) are process sectional views illustrating a manufacturing process of the solar cell according to the first embodiment.

FIG. 5 is a diagram illustrating a mask for opening a passivation film according to the first embodiment.

FIG. 6 is a diagram illustrating a measurement result of characteristics of the solar cell according to the first embodiment and a solar cell according to a comparative example.

FIG. 7 is a diagram schematically illustrating a solar cell according to a second embodiment.

FIGS. 8(a) to (c) are process sectional views illustrating a manufacturing process of the solar cell according to the second embodiment.

FIGS. 9(a) to (c) are process sectional views illustrating a manufacturing process of the solar cell according to the second embodiment.

FIGS. 10(a) to (c) are process sectional views illustrating a manufacturing process of a solar cell according to a third embodiment.

FIGS. 11 (a) to (c) are process sectional views illustrating a manufacturing process of the solar cell according to the third embodiment.

FIG. 12 is a plan view of an etching paste mask to be used in a manufacturing method for a solar cell according to a fourth embodiment.

FIG. 13 is a plan view schematically illustrating a solar cell formed by the manufacturing method for a solar cell according to the fourth embodiment.

FIG. 14(a) is a sectional view along a line B-B′ in FIG. 13, and FIG. 14(b) is a sectional view along a line C-C′ in FIG. 13.

FIG. 15 is a plan view of a modification of the etching paste mask to be used in the manufacturing method for a solar cell according to the fourth embodiment.

FIG. 16 is a plan view of an etching paste mask to be used in a manufacturing method for a solar cell according to a fifth embodiment.

FIG. 17 is a diagram illustrating a mask shape for forming a metal electrode used in the manufacturing method for a solar cell according to the fifth embodiment.

FIGS. 18(a) and 18(b) are diagrams schematically illustrating a solar cell formed by the manufacturing method for a solar cell according to the fifth embodiment, where FIG. 18(a) is a sectional view corresponding to a sectional view along a line B-B′ in FIG. 13, and FIG. 18(b) is a sectional view corresponding to a sectional view along a line C-C′ in FIG. 13.

FIGS. 19(a) and 19(b) are diagrams schematically illustrating a solar cell manufactured by a manufacturing method for a solar cell according to a sixth embodiment, where FIG. 19(a) is a sectional view corresponding to the sectional view along a line B-B′ in FIG. 13, and FIG. 19(b) is a sectional view corresponding to the sectional view along a line C-C′ in FIG. 13.

### DESCRIPTION OF EMBODIMENTS

Exemplary embodiments of a manufacturing method for a solar cell and a solar cell according to the present invention will be explained below in detail with reference to the accompanying drawings. The present invention is not limited to the embodiments and can be modified as appropriate without departing from the scope of the invention. In the drawings described below, the scale of each layer or each member may be different from the actual scale for easier understanding, and the same applies in the respective drawings. Further, even in a plan view, hatching may be applied in order to facilitate visualization of the drawings.

### First Embodiment

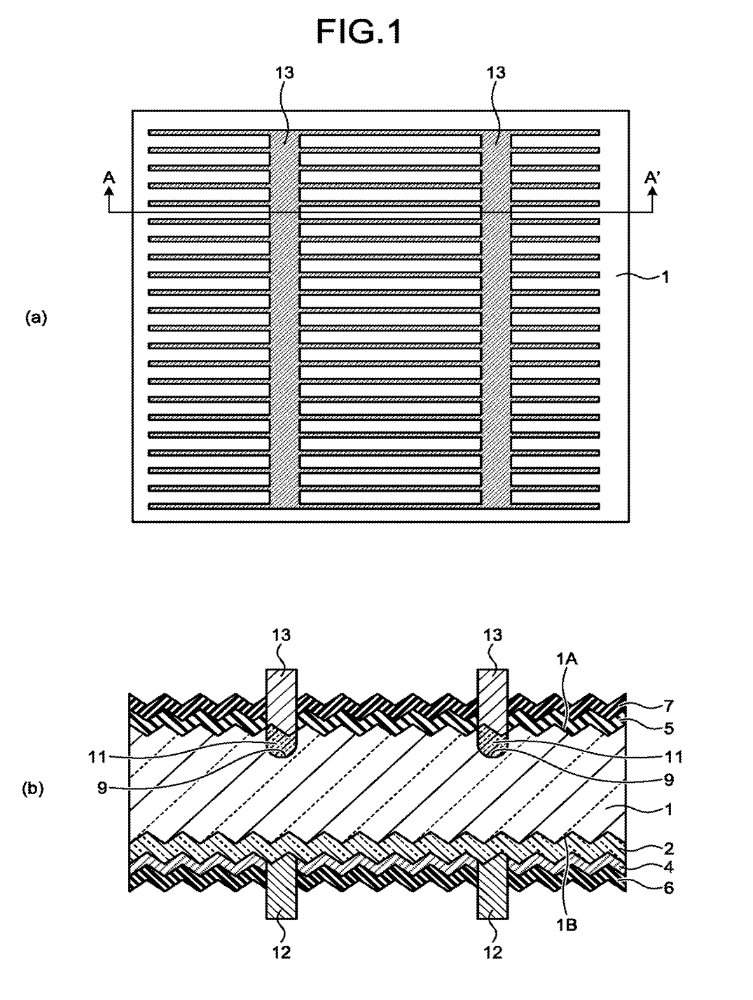

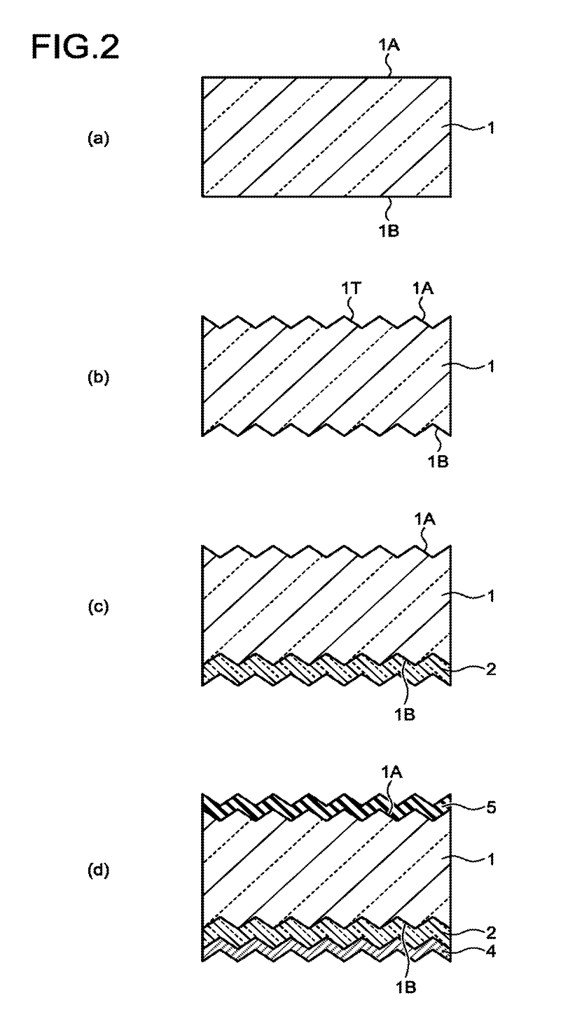

FIGS. 1(a) and 1(b) are diagrams schematically illustrating a solar cell according to a first embodiment of the present invention, where FIG. 1(a) is a plan view, and FIG. 1(b) is a sectional view along a line A-A′ in FIG. 1(a). FIGS. 2(a) to 2(d), FIGS. 3(a) to 3(d), and FIGS. 4(a) to 4(c) are manufacturing process diagrams of the solar cell. A diffusion solar cell (hereinafter, also “solar cell”), which is an example of a crystalline solar cell and a manufacturing method therefor is described in the present embodiment.

In the present embodiment, a second conductivity-type diffusion region is formed on a first conductivity-type silicon substrate, and a passivation film consisting of a laminated film of a silicon oxide (SiO₂) film 4 or 5 and a silicon nitride (SiN) film 6 or 7 is formed on a silicon substrate, which forms a pn junction. As the first conductivity-type silicon substrate, a substrate in which a p-type diffusion layer 2 is formed as a second conductivity-type diffusion region on an n-type silicon substrate 1 having a first principal surface as a light receiving surface 1A and a second principal surface as a back surface 1B is used. An open region 9 is formed in the passivation film (the SiO₂ film 5 and the SiN film 7) on the side of the light receiving surface 1A, and n-type impurities are diffused with respect to the open region 9 by using the passivation film as a mask to form a high-concentration diffusion region 11. A collecting electrode is then formed in alignment with the open region 9 of the passivation film. A case where the n-type silicon substrate 1 is used as the first conductivity-type silicon substrate is described here. However, a silicon substrate having p-type conductivity can be also used. As an example of a semiconductor substrate, an n-type crystalline silicon substrate is used. The crystalline silicon substrate includes a monocrystalline silicon substrate and a polycrystalline silicon substrate. However, it is particularly preferable to use the monocrystalline silicon substrate having a (100) surface as a surface.

As illustrated in FIG. 2(a), for example, it is preferable to use the n-type silicon substrate 1 in which slice damage caused by slicing a silicon ingot is removed. The slice damage can be removed by etching using mixed acid of a hydrogen fluoride aqueous solution (HF) and nitric acid (HNO₃) or an alkaline aqueous solution such as NaOH. The shape and size of the n-type silicon substrate 1 are not particularly limited. However, the thickness thereof is preferably from 80 micrometers to 400 micrometers inclusive. The surface shape of the n-type silicon substrate 1 is preferably a square shape, for example, in which the length of one side is from 90 millimeters to 160 millimeters inclusive. The specific resistance thereof is preferably from 1.0 Ω·cm to 10.0 Ω·cm inclusive.

As illustrated in FIG. 2(b), a texture 1T is formed on both surfaces of the n-type silicon substrate 1. The n-type silicon substrate 1 is immersed in an etching tank to perform wet etching. After the wet etching is performed, the texture 1T formed of micro pyramids having a height from 8 micrometers to 21 micrometers inclusive and a base length from 1 micrometer to 30 micrometers inclusive is formed at random on the surfaces of the n-type silicon substrate 1. The micro pyramid is a triangular pyramid consisting primarily of a silicon (111) surface. Surface roughness of the back surface 1B of the n-type silicon substrate 1 in an n-type semiconductor junction region is, for example, about 0.2 nanometer. As for the etching solution used for the wet etching described above, an alcoholic additive such as isopropyl alcohol, a surface acting agent, or a silicate compound such as sodium orthosilicate is added to a solution in which a strong alkaline reagent such as sodium hydroxide, potassium hydroxide, or tetramethylammonium hydroxide is dissolved. The etching temperature is preferably from 40° C. to 100° C. inclusive, and the etching time is preferably from 10 minutes to 60 minutes inclusive.

To clean the surface of the n-type silicon substrate 1, first and second processes described below are performed. In the first process, the n-type silicon substrate 1 is immersed in a cleaning solution containing concentrated sulfuric acid and a hydrogen peroxide solution to remove organic substances on the surface of the n-type silicon substrate 1 and an n-type oxide film on the n-type silicon substrate 1 formed at this time is removed in a hydrofluoric acid solution. In the second process, the n-type silicon substrate 1 is immersed in a cleaning solution containing hydrochloric acid and a hydrogen peroxide solution to remove metal impurities, and an oxide film formed on the surface of the n-type silicon substrate 1 formed at this time is removed in a hydrofluoric acid solution. The first and second processes are repeatedly performed until organic contamination, metal contamination, and contamination by particles on the surface of the n-type silicon substrate 1 are sufficiently reduced. Cleaning can be performed by functional water such as ozone water or carbonated water.

As illustrated in FIG. 2(c), boron is diffused on the side of the back surface 1B of the n-type silicon substrate 1 to form a p-type diffusion layer 2, that is, a p⁺ layer. A solid-phase diffusion method is used as a method for forming the p-type diffusion layer 2. A boron silicate glass (BSG) that is a silicon oxide film containing boron is formed on the side of the light receiving surface 1A, which is the first principal surface. An APCVD (Atmospheric Pressure Chemical Vapor Deposition) method is used for forming the silicon oxide film. Gas used for film formation is SiH₄, B₂H₆, and O₂. The film formation temperature is equal to or higher than 400° C. The film thickness of the BSG is from about 100 nanometers to about 300 nanometers.

Thereafter, to diffuse boron, a high-temperature annealing treatment at a temperature of 900° C. or higher is performed. A device to be used is a horizontal diffusion furnace. The concentration of boron to be diffused on the back surface 1B of the n-type silicon substrate 1 is adjusted in a range from 1.0×10¹⁷/cm³ to 1.0×10²⁰/cm³ inclusive.

As a method for diffusing boron, a vapor-phase diffusion method for diffusing boron in a high-temperature electric furnace by using B₂H₆, BCl₃, or the like as a gas source, an ion implantation method in which boron is ionized and implanted into the n-type silicon substrate 1, or the like can be used.

As illustrated in FIG. 2(d), the silicon oxide films 4 and 5 are formed respectively on the surfaces of the n-type silicon substrate 1 as a passivation film. At the time of film formation, cleaning is performed with respect to the surface of the n-type silicon substrate 1 before film formation. As cleaning before film formation, first and second processes described below are performed as in the same manner after the wet etching. In the first process, organic substances on the surface of the n-type silicon substrate 1 are removed by a cleaning solution containing concentrated sulfuric acid and a hydrogen peroxide solution, and an oxide film formed at this time is removed by HF. In the second process, metal impurities are removed by a cleaning solution containing hydrochloric acid and a hydrogen peroxide solution, and an oxide film formed at this time on the surface of the n-type silicon substrate 1 is removed by a hydrofluoric acid solution. The first and second processes are repeatedly performed until organic contamination, metal contamination, and contamination by particles on the surface of the n-type silicon substrate 1 are sufficiently reduced. Cleaning can be performed by functional water such as ozone water or carbonated water.

Further, before forming the passivation film, a process of removing a boron-containing film such as BSG is performed. However, a method for diffusing phosphorus as an n-type diffusion layer on the side of the back surface 1B that is a non-light receiving surface can be used while leaving the boron-containing film such as BSG formed thereon. Alternatively, a vapor-phase diffusion method for diffusing boron in a high-temperature electric furnace by using POCl₃ or the like as a gas source, an ion implantation method in which boron is ionized and implanted into the silicon substrate, or the like can be used.

The silicon oxide (SiO₂) films 4 and 5 are formed respectively on each surface of the back surface 1B and the light receiving surface 1A of the n-type silicon substrate 1 by dry oxidation. The dry oxidation is performed by using a high-temperature electric furnace. The SiO₂ films 4 and 5 are formed by feeding high-purity oxygen onto the n-type silicon substrate 1. The film formation temperature is preferably from 900° C. to 1200° C. inclusive. The film formation time is preferably from 15 minutes to 60 minutes inclusive. The film is formed with a thickness from 10 nanometers to 40 nanometers inclusive. SiO₂ functions as a passivation film on the surface of the n-type silicon substrate 1. In film formation on a silicon interface in the n-type silicon substrate 1, aluminum oxide (Al₂O₃), a microcrystalline silicon thin film, an amorphous silicon thin film, or the like can be used as the passivation film. Alternatively, a laminated film with a silicon oxide film can be used.

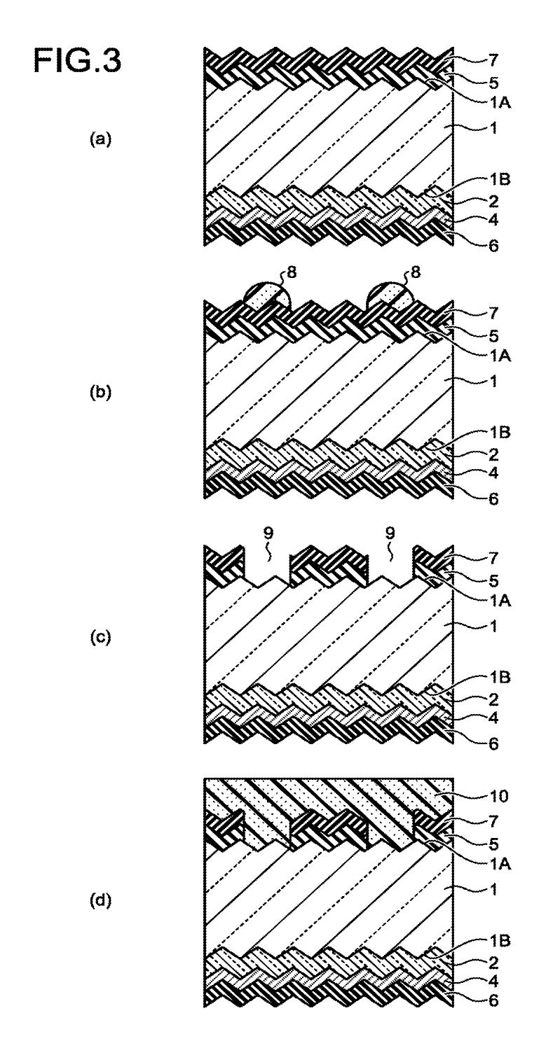

As illustrated in FIG. 3(a), the silicon nitride (SiN) films 6 and 7 are respectively formed on the side of the light receiving surface 1A and on the side of the back surface 1B of the n-type silicon substrate 1. These silicon nitride films 6 and 7 assume a role as a passivation film consisting of a laminated film, together with the silicon oxide films 4 and 5. The APCVD method is used for film formation of the SiN films 6 and 7. The gas to be used for film formation is SiH₄, N₃, NH₃, and O₂. The film formation temperature is equal to or higher than 300° C. The film thickness of the SiN film is from about 10 nanometers to about 200 nanometers inclusive.

Because SiN has a positive fixed charge, the passivation effect can be further increased particularly on the n-side silicon interface on the n-type silicon substrate. On the light receiving surface side, the SiN film can be used as an antireflection film in addition to the high passivation effect.

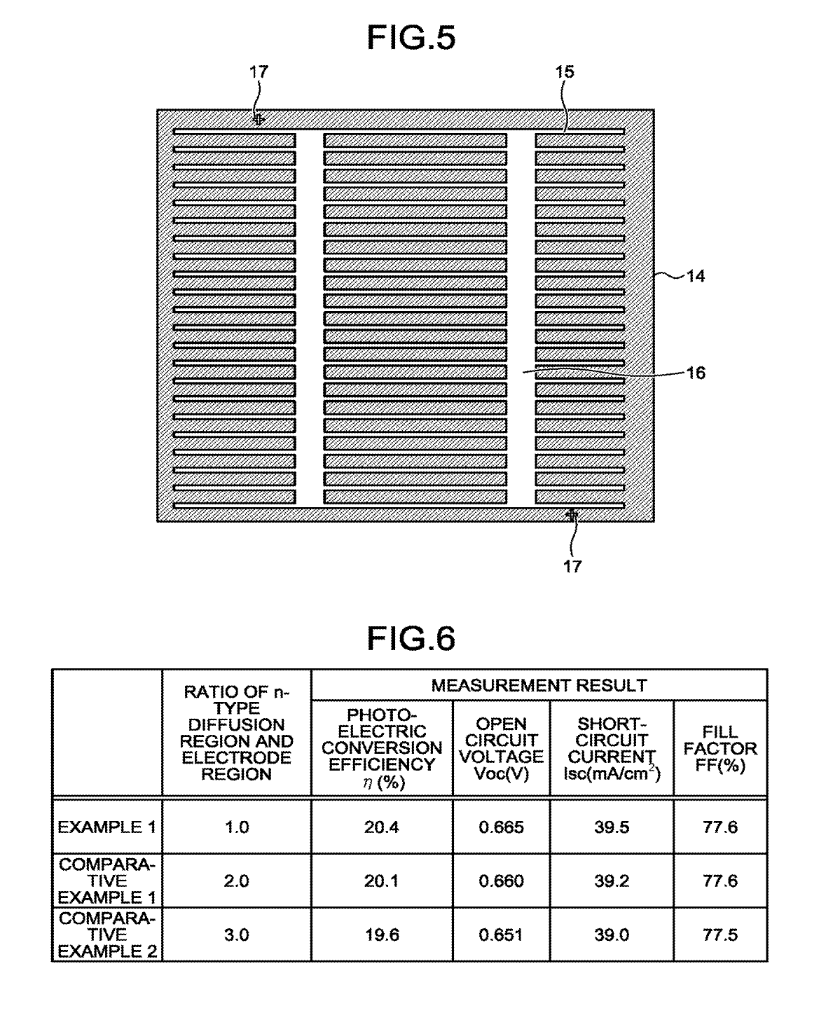

The laminated film of the SiO₂ film 5 and the SiN film 7 formed as the passivation film on the light receiving surface 1A of the n-type silicon substrate 1, which is an opposite surface to a surface on which the p-type diffusion layer 2, that is, the p⁺ layer is formed, is etched in an arbitrary pattern. As the etching method, an etching paste 8 is first screen printed as illustrated in FIG. 3(b) in an arbitrary pattern. A mask 14 to be used for screen printing of the etching paste 8 has a comb shape. For example, screen printing is performed via the mask 14 including openings 15 for a grid electrode and openings 16 for a bus electrode orthogonal thereto illustrated in a plan view in FIG. 5. In addition, an alignment mark 17 is respectively provided on the lower right and the upper left of the mask 14. In the present embodiment, a cross-shaped mark is used.

An etching paste containing an etching component capable of etching the laminated film described above, and water, an organic solvent, a thickener, and the like as components other than the etching component can be used as the etching paste 8. As the etching component, at least one component selected from phosphoric acid, hydrogen fluoride, ammonium fluoride, and ammonium hydrogen fluoride is used.

After the etching paste 8 has been printed, the laminated film of the SiO₂ film 5 and the SiN film 7 is etched by burning for 1 minute or more at a temperature of 100° C. or higher. The burning temperature or the burning time for etching are changed according to a composition of the etching component of the etching paste 8 and a film composition of the laminated film of the SiO₂ film 5 and the SiN film 7. By etching the laminated film of the SiO₂ film 5 and the SiN film 7 by using the etching paste 8, the open region 9 is formed as illustrated in FIG. 3(c).

As the method for etching the laminated film of the SiO₂ film 5 and the SiN film 7, photolithography or laser can be used.

After the etching paste 8 is printed, ultrasonic cleaning by an ultrasonic bath is performed in pure water or in a sodium hydroxide solution having a low concentration of 1.0% or lower to completely remove a residue of the etching paste 8. A cleaning solution containing concentrated sulfuric acid and a hydrogen peroxide solution or functional water such as hydrofluoric acid or ozone water can be used.

Phosphorus is then diffused in the open region 9 to form the high-concentration n-type diffusion layer, that is, n⁺ layer as the high-concentration diffusion region 11. As a method for forming the n⁺ layer, a dopant paste 10 is used. The dopant paste 10 containing n-type impurities such as phosphorus and components such as water, an organic solvent, and a thickener is applied thereto by screen printing as illustrated in FIG. 3(d). When screen printing is performed by applying the dopant paste 10, printing is performed onto the whole surface of the n-type silicon substrate 1. Because a region to be printed is the whole surface of the n-type silicon substrate 1, a mask formed with a fine pattern is not required. The open region 9 in the laminated film of the SiO₂ film 5 and the SiN film 7 is used instead of a mask.

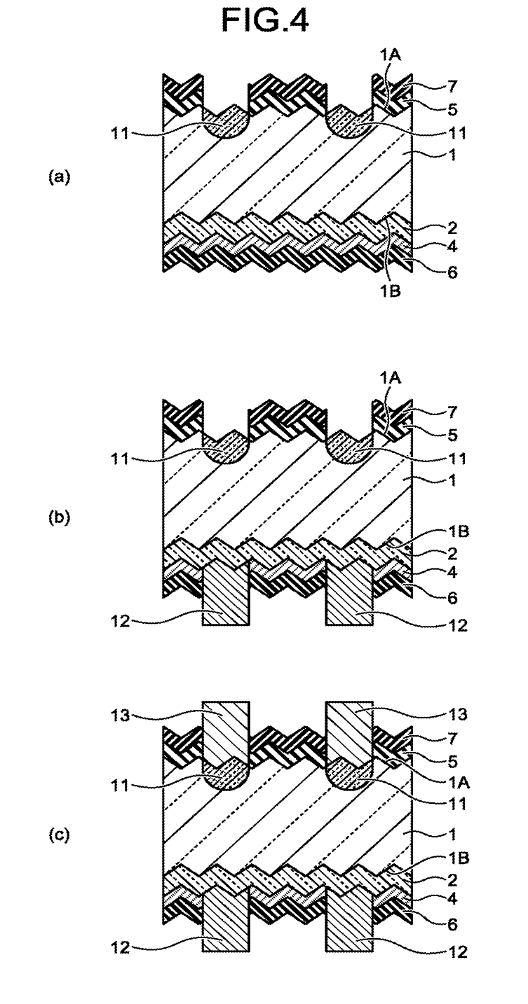

After the dopant paste 10 is applied, the dopant paste 10 is heated at a high temperature of 800° C. or higher to diffuse phosphorus contained in the dopant paste 10 in the open region 9. As illustrated in FIG. 4(a), the n⁺-type high-concentration diffusion region 11 is diffused on the n-type silicon substrate 1. A device to be used is a horizontal diffusion furnace. The concentration of phosphorus to be diffused in the open region 9 of the n-type silicon substrate 1 is adjusted in a range from 1.0×10¹⁷/cm³ to 1.0×10²¹/cm³ inclusive. If the phosphorus concentration is less than 1.0×10¹⁷/cm³, the influence of improvement of the passivation effect by the surface field effect can be hardly acquired. If the phosphorus concentration exceeds 1.0×10²¹/cm³, the influence of Auger recombination increases and the characteristics thereof deteriorate. With regard to the laminated film of the SiO₂ film 5 and the SiN film 7 used as a mask of the dopant paste 10, because phosphorus is hardly implanted particularly into the SiN film 7 as compared with Si, the silicon nitride film 7 diffused thinner than the entire film thickness can be removed by etching using hydrofluoric acid. Because the laminated film of the SiO₂ film 5 and the SiN film 7 to be used as the passivation film is used as a mask, the region in which the n⁺-type high-concentration diffusion region 11 is diffused on the n-type silicon substrate 1 is limited to the open region 9 opened by the etching paste 8. Because the dopant is hardly diffused in SiN, full-face printing can be performed with respect to the n-type silicon substrate 1.

As the method for diffusing phosphorus, a vapor-phase diffusion method for diffusing phosphorus in a high-temperature electric furnace by using POCl₃, PH₃, or the like as a gas source, or an ion-implantation method in which phosphorus is ionized and implanted into the silicon substrate, or the like can be used. In the diffusion methods described above, the laminated film of the SiO₂ film 5 and the SiN film 7 is used as a mask layer.

After the dopant paste 10 is printed, ultrasonic cleaning by an ultrasonic bath is performed by immersing the dopant paste 10 in pure water to remove a residue of the dopant paste 10 completely. A cleaning solution containing concentrated sulfuric acid and a hydrogen peroxide solution or functional water such as ozone water can be used.

Particularly after the dopant paste 10 is removed, it is necessary to perform etching of the SiN film 7 by using hydrofluoric acid in order to remove a region in which phosphorus is thinly diffused in the film of the SiN film 7. Particularly, because a depth of phosphorus diffused in the film of the SiN film 7 is thinner than that in the n-type silicon substrate 1, etching is performed for about 10 nanometers. The concentration of hydrofluoric acid or etching time is changed according to a film composition of the SiN film 7. This time, etching is performed for 30 seconds by hydrofluoric acid having a concentration of 5.0%. The same process is required also in the vapor-phase diffusion and the ion implantation.

Metal electrodes 12 and 13 are then formed on the both surfaces of the n-type silicon substrate 1. As illustrated in FIG. 4(b), the metal electrode 12 is first formed on the side of the back surface 1B that is the second principal surface, and bonded to the p-type diffusion layer 2, that is, the p⁺ layer. Particularly, as the method for bonding the metal electrode 12 to the p-type diffusion layer 2, after the laminated film of the SiO₂ film 4 and the SiN film 6 is opened by an etching paste, laser opening, or photolithography, a conductive paste made of only Al or a mixed material of Al and Ag is screen printed and applied thereto. Thereafter, the n-type silicon substrate 1 is burned at a high temperature of 600° C. or higher in order to form the high concentration p-type diffusion layer 2 in an electrode bonding part.

As the method for bonding the metal electrode 12 to the p-type diffusion layer 2, after a conductive paste made of only Al or a mixed material of Al and Ag is screen printed, a fire-through process can be performed on the laminated film of the SiO₂ film 4 and the SiN film 6 at a high temperature of 700° C. or higher, thereby bonding the metal electrode 12 to the p-type diffusion layer 2.

As illustrated in FIG. 4(c), the metal electrode 13 is formed on the side of the light receiving surface 1A of the n-type silicon substrate 1 and bonded to the n⁺-type high-concentration diffusion region 11. Particularly, as the method for bonding the metal electrode 13 to the n⁺-type high-concentration diffusion region 11, a conductive paste containing Ag is screen printed and applied thereto. As a mask, the mask 14 enlarged within 50 micrometers respectively from both ends in accordance with the line width of the mask 14 illustrated in FIG. 5 is used. The above pattern takes into consideration a width of misalignment of the mask 14. The conductive paste is applied to the region of the n⁺-type high-concentration diffusion region 11 on the n-type silicon substrate 1.

Burning is performed to decrease contact resistance between the n⁺-type high-concentration diffusion region 11 and the metal electrode 13. Although depending on the property of the conductive paste, burning is performed this time at about 200° C. in a burning furnace. As a method for bonding the metal electrode 13 to the high-concentration diffusion region 11, that is, the n⁺ layer, a method in which metal such as Ni or Ti is plated to the metal electrode as a seed layer to grow Ag or Cu thereon, to form the metal electrode 13 on the n⁺-type high-concentration diffusion region 11 can be also applied. By using the plating technique, the influence of a bleeding component of the conductive paste due to the screen printing can be removed, thereby enabling to collect light in a wider range.

As illustrated in FIG. 4(c), an n-type diffusion solar cell is manufactured in the manner as described above. A back emitter structure in which the p⁺ layer as an emitter layer, that is, the p-type diffusion layer 2 is on the back surface side is used. However, a front emitter structure in which the p-type diffusion layer 2 is on the side of the light receiving surface 1A can be used.

Subsequently, the manufactured n-type diffusion solar cell was actually activated, and power generation characteristics thereof were measured and evaluated. The solar cell manufactured according to the first embodiment is referred to as Example 1. As comparative examples, solar cells of comparative examples 1 and 2 were manufactured. The relation between a ratio of a surface area of the n-type diffusion region to a surface area of an electrode forming region and an incident photoelectric conversion efficiency η (%), an open circuit voltage Voc (V), a short-circuit current Isc (mA/cm²), and a fill factor FF (%) is illustrated in a table of FIG. 6.

In the n-type diffusion solar cell having the structure illustrated in comparative example 1, before forming the laminated film of the SiO₂ film 5 and the SiN film 7 that is a passivation film, screen printing is performed with respect to the n layer on the side of the light receiving surface 1A by using the dopant paste described above to diffuse phosphorus thereon, thereby forming the high-concentration n⁺ layer, that is, the high-concentration diffusion region 11. The concentration of boron to be diffused is substantially the same extent as that of the first embodiment. As for the printing mask, a mask in which both ends thereof are enlarged by 100 micrometers respectively in accordance with the line width of the mask 14 illustrated in FIG. 5 is used. After phosphorus is diffused by using the dopant paste, the laminated film of the SiO₂ film 5 and the SiN film 7 is formed by the above process, and the laminated film of the SiO₂ film 5 and the SiN film 7 is opened by the etching paste formed via the mask 14 in FIG. 5. Processes other than those described above are the same as in the first embodiment.

In the n-type diffusion solar cell having the structure illustrated in comparative example 2, before forming the laminated film of the SiO₂ film 5 and the SiN film 7 that is a passivation film, screen printing is performed with respect to the n layer on the side of the light receiving surface 1A by using the dopant paste described above to diffuse phosphorus thereon, thereby forming the n⁺-type high-concentration diffusion region. The concentration of boron to be diffused is substantially the same extent as that of the first embodiment. As for the printing mask, a mask in which both ends thereof are enlarged by 200 micrometers respectively in accordance with the line width of the mask 14 illustrated in FIG. 5 is used. Processes other than those described above are the same as in the comparative example 1.

As can be understood from a table illustrated in FIG. 6, when the n-type diffusion layer is implanted into a silicon substrate with high concentration, by decreasing the ratio of the n⁺-type high-concentration diffusion region 11 and the metal electrode 13 that is an electrode region, the open circuit voltage and the short-circuit current are improved. As a factor of improving the open circuit voltage and the short-circuit current, it can be mentioned that the carriers generated by sunlight in the impurity diffusion region recombine in the high-concentration diffusion region 11 and do not contribute to light conversion. However, if there is no high-concentration diffusion region 11, that is, n-type diffusion region, the passivation effect by means of the surface field effect cannot be acquired, which leads to a decrease of the open circuit voltage and a decrease of the fill factor due to an increase of the ohmic contact resistance with the metal electrode 13.

According to the method for forming the n⁺-type high-concentration diffusion region 11 before film formation of the laminated film of the SiO₂ film 5 and the SiN film 7, it is necessary to consider misalignment in each process. Therefore, it is necessary to design the n⁺-type high-concentration diffusion region 11 with a larger design width than the electrode width. Accordingly, if the n⁺-type high-concentration diffusion region 11 is formed by the method of the present invention, the n⁺-type high-concentration diffusion region 11 can be formed approximately in the same region as the electrode forming region.

In the first embodiment, phosphorus is used as the n-type impurities that form the high-concentration diffusion region 11. However, the n-type impurities are not limited to phosphorus, and other elements of Group V such as arsenic As and antimony Sb can be used.

As described above, according to the present invention, because high-concentration n-type impurities are diffused by using the passivation film as a mask, the high-concentration diffusion region is formed substantially in the same region as a bonding surface between the silicon substrate surface and the metal electrode. Accordingly, the high-concentration diffusion region that does not contribute to light conversion can be made narrower than that in the case where the high-concentration diffusion region is diffused before forming the passivation film. Further, alignment between the high-concentration diffusion region and the open region of the passivation film in mask design is not required, thereby enabling to form the selective emitter structure only by alignment between the open region of the passivation film and the metal electrode in the mask design. Therefore, according to the present invention, the n⁺-type high-concentration diffusion region can be formed substantially in the same region as a region abutting on the metal electrode, thereby enabling to acquire a solar cell having a high incident photoelectric conversion efficiency.

### Second Embodiment

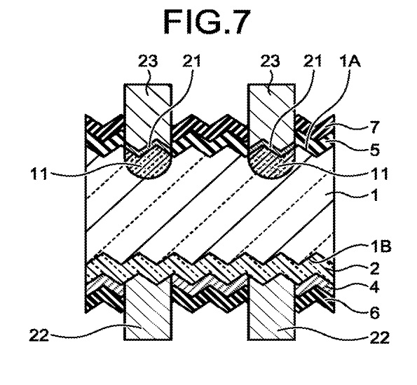

As a second embodiment of the present invention, a solar cell in which a metal electrode 23 is formed by using a selective plating method instead of forming a metal electrode by printing is described. The solar cell is different from that of the first embodiment, as illustrated in FIG. 7, only in a point that the electrode on the side of the light receiving surface 1A is the metal electrode 23 formed by selective plating via an underlayer 21. That is, the underlayer 21 and the metal electrode 23 formed by selective plating of copper are formed so as to coincide with the open region 9 in the passivation film consisting of the laminated film of the SiO₂ film 5 and the SiN film 7. Further, a metal electrode on the side of the back surface 1B is configured by a metal electrode 22 by copper plating. Other elements are identical to those of the first embodiment, and thus descriptions thereof are omitted here. Constituent elements identical to those of the first embodiment are denoted by like reference signs.

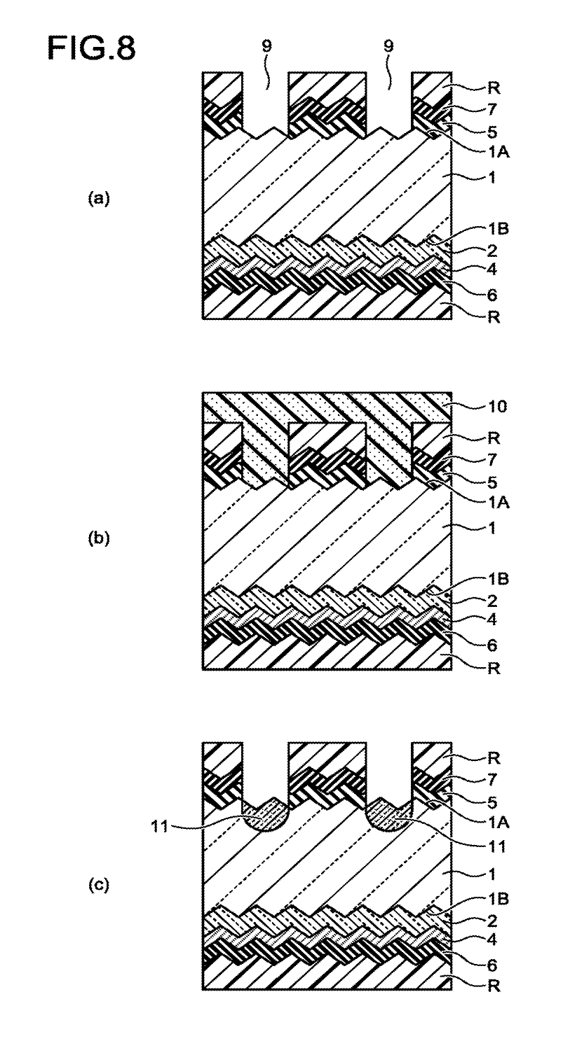

In the first embodiment described above, as illustrated in FIG. 3(a), after the silicon nitride films (SiN) 6 and 7 are respectively formed on the side of the light receiving surface 1A and the side of the back surface 1B of the n-type silicon substrate 1, the etching paste 8 is formed. However, in the present embodiment, as illustrated in FIG. 8(a), a resist pattern R is formed by photolithography for forming the open region 9 instead of forming the etching paste. The resist pattern R is also formed on the side of the back surface 1B by application on the whole surface.

Subsequently, by performing etching using the resist pattern R as a mask, etching is performed in an arbitrary pattern in which the open region 9 is formed in the laminated film of the SiO₂ film 5 and the SiN film 7 that is formed as a passivation film on the light receiving surface 1A, which is a surface opposite to the p-type diffusion layer 2 of the n-type silicon substrate 1, that is, a surface where the p⁺ layer is formed. As the etching method, wet etching or dry etching can be used so long as it is anisotropic etching. At this time, as a mask, if a negative resist is to be used, it is sufficient to use a mask having a reverse pattern of a pattern including the openings 15 for a grid electrode and the openings 16 for a bus electrode orthogonal thereto illustrated in the plan view in FIG. 5 in the first embodiment. On the other hand, if a positive resist is to be used, the mask can be used.

Subsequently, by diffusing phosphorus in the open region 9 while leaving the resist pattern R, a high-concentration n-type diffusion layer as the high-concentration diffusion region 11 is formed. As a method for forming the n⁺ layer, the dopant paste 10 is used. The dopant paste 10 containing n-type impurities such as phosphorus and components such as water, an organic solvent, and a thickener is applied thereto by screen printing as illustrated in FIG. 8(b). When screen printing is performed by applying the dopant paste 10, printing is performed onto the whole surface of the n-type silicon substrate 1. Because a region to be printed is the whole surface of the n-type silicon substrate 1, a mask formed with a fine pattern is not required. The open region 9 in the laminated film of the SiO₂ film 5 and the SiN film 7 is used instead of a mask.

After the dopant paste 10 is applied, the dopant paste 10 is heated at a high temperature of 800° C. or higher to diffuse phosphorus contained in the dopant paste 10 in the open region 9. As illustrated in FIG. 8(c), the n⁺-type high-concentration diffusion region 11 is diffused on the n-type silicon substrate 1. A device to be used is a horizontal diffusion furnace. The concentration of phosphorus to be diffused in the open region 9 of the n-type silicon substrate 1 is adjusted in a range from 1.0×10¹⁷/cm³ to 1.0×10²¹/cm³ inclusive. If the phosphorus concentration is less than 1.0×10¹⁷/cm³, the influence of improvement of the passivation effect by the surface field effect can be hardly acquired. If the phosphorus concentration exceeds 1.0×10²¹/cm³, the influence of Auger recombination increases and the characteristics thereof deteriorate. With regard to the laminated film of the SiO₂ film 5 and the SiN film 7 used as a mask of the dopant paste 10, because phosphorus is hardly implanted particularly into the SiN film 7 as compared with Si, the SiN film 7 diffused thinner than the entire film thickness can be removed by etching using hydrofluoric acid. Because the laminated film of the SiO₂ film 5 and the SiN film 7 to be used as the passivation film is used as a mask, the region in which the n⁺-type high-concentration diffusion region 11 is diffused on the n-type silicon substrate 1 is limited to the open region 9 opened by the resist pattern R described above. Because the dopant is hardly diffused in SiN, full-face printing can be performed with respect to the n-type silicon substrate 1.

As the method for diffusing phosphorus, a vapor-phase diffusion method for diffusing phosphorus in a high-temperature electric furnace by using POCl₃, PH₃, or the like as a gas source, or an ion-implantation method in which phosphorus is ionized and implanted into the silicon substrate, or the like can be used. In the diffusion methods described above, the laminated film of the SiO₂ film 5 and the SiN film 7 is used as a mask layer.

After the dopant paste 10 is printed, ultrasonic cleaning by an ultrasonic bath is performed by immersing the dopant paste 10 in pure water to remove a residue of the dopant paste 10 completely. A cleaning solution containing concentrated sulfuric acid and a hydrogen peroxide solution or functional water such as ozone water can be used.

Particularly after the dopant paste 10 is removed, it is necessary to perform etching of the SiN film 7 by using hydrofluoric acid in order to remove a region in which phosphorus is thinly diffused in the film of the SiN film 7. Particularly, because a depth of phosphorus diffused in the film of the SiN film 7 is thinner than that in the n-type silicon substrate 1, etching is performed for about 10 nanometers. The concentration of hydrofluoric acid or the etching time is changed according to a film composition of the SiN film 7. This time, etching is performed for 30 seconds by hydrofluoric acid having a concentration of 5.0%. The same process is required also in the vapor-phase diffusion and the ion implantation.

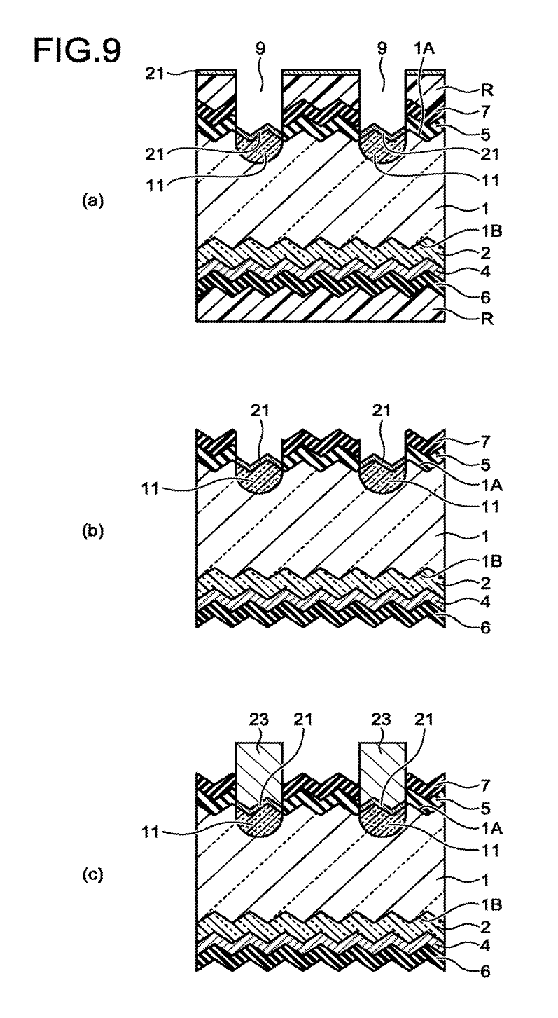

Metal electrodes 22 and 23 are then formed on the both surfaces of the n-type silicon substrate 1. First, as illustrated in FIG. 9(a), the underlayer 21 consisting of a two-layer film of an Ni layer and a Cu layer is formed by sputtering on the side of the light receiving surface 1A that is the first principal surface.

The resist pattern R is then peeled off. At this time, the underlayer 21 on the resist pattern R is removed, and as illustrated in FIG. 9(b), the underlayer 21 is formed only in the open region 9.

Thereafter, as illustrated in FIG. 9(c), the metal electrode 23 formed of a Cu plating layer is formed by electrolytic plating using the underlayer 21 as a seed layer.

The metal electrode 22 is also formed on the side of the second principal surface 1B, thereby forming the solar cell illustrated in FIG. 7. The metal electrode 23 can be a printed electrode as in the first embodiment, or a plated electrode.

According to the present embodiment, by using an underlayer formed of a metal film as a seed layer to perform plating, a metal electrode can be formed. A highly accurate electrode pattern can be formed as compared to a printed electrode.

As the underlayer, Ni, Ti, or a laminated film can be used. By plating metal such as Ag or Cu using these underlayers as a seed layer, a selective plating layer can be caused to grow to be formed on the n⁺-type high-concentration diffusion region 11. The film forming method of the underlayer is not limited to the sputtering method, and electroless plating can be used. Also in this case, by immersing a resist pattern used for patterning of the passivation film in a plating solution as it is, an underlayer consisting of an electroless plating layer can be formed only in the open region 9.

Further, by using electrode formation by performing plating using the electroless plating layer as an underlayer, the first and second principal surfaces can be formed simultaneously.

### Third Embodiment

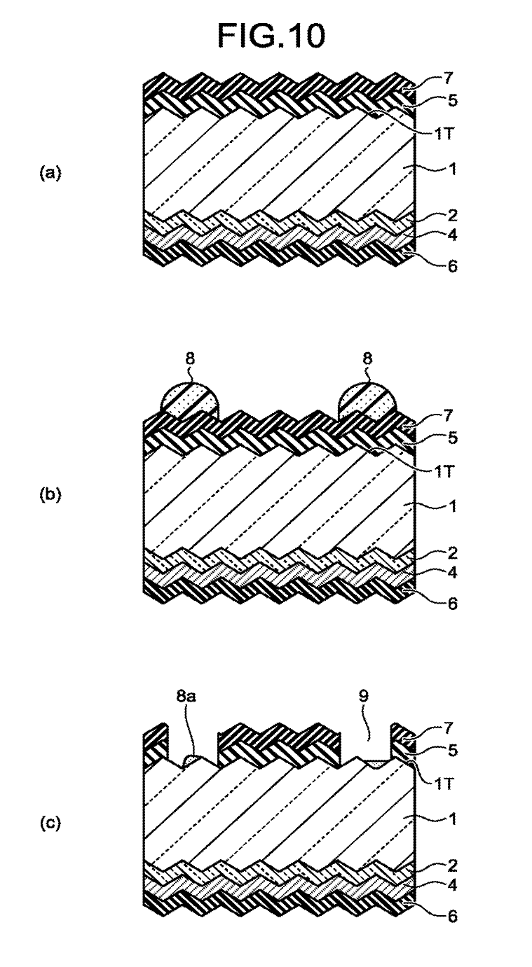

A third embodiment of the present invention is described with reference to a solar cell manufacturing process diagram in FIG. 10. This method is a method for processing the texture 1T of the n-type silicon substrate 1 using the open region 9 as a mask, in addition to the method for selectively etching only the laminated film of the SiO₂ film 5 and the SiN film 7 by an etching paste to form the open region 9. According to the present embodiment, after the open region 9 is formed by etching the laminated film of the SiO₂ film 5 and the SiN film 7 by the etching paste 8, an etching paste residue 8a is removed by using a high-concentration alkaline solution, and the texture 1T of the n-type silicon substrate 1 is processed. Other elements are identical to those of the first embodiment, and thus descriptions thereof are omitted here. Constituent elements identical to those of the first embodiment are denoted by like reference signs.

In the first embodiment, there is used a method in which after the open region 9 is formed by using the etching paste 8, ultrasonic cleaning is performed in pure water or the sodium hydroxide solution having a low concentration of 1.0% or lower to remove the etching paste residue. The sodium hydroxide solution having a low concentration of 1.0% or lower is a solvent having selectivity so that the silicon nitride (SiN) films 6 and 7 and the texture 1T of the n-type silicon substrate 1 are not etched. The sodium hydroxide solution can remove the etching paste residue while maintaining the texture shape in the open region 9 and the size thereof.

However, as illustrated in FIG. 10(c), if the laminated film of the SiO₂ film 5 and the SiN film 7 is etched by the etching paste 8, it is necessary to burn the laminated film at a high temperature of 100° C. or higher in order to improve the processing accuracy. At this time, the etching paste residue 8a that is a reaction product or the like such as an organic solvent and a thickener, which are components other than the etching component of the etching paste 8, may remain. If the etching paste residue 8a remains in the open region 9, when a dopant paste containing phosphorus to be formed thereafter is diffused in the open region 9, sufficient diffusion may not be performed in the n-type silicon substrate 1 and contact resistance is increased, thereby causing characteristics deterioration. Therefore, it is necessary to remove the etching paste residue 8a reliably.

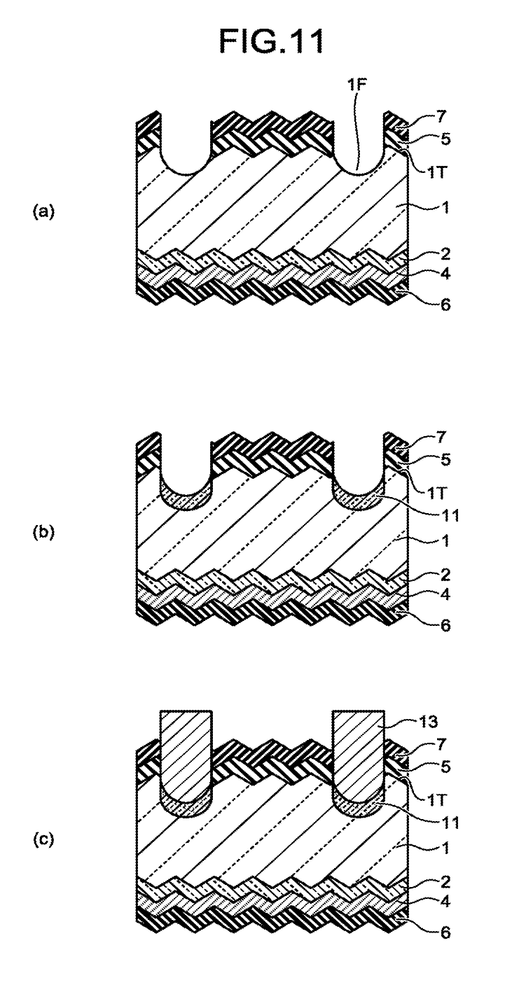

In the third embodiment, as illustrated in FIGS. 10(a) to 10(c), after the etching paste 8 has been printed, burning is performed at a temperature of 100° C. or higher for one minute or more and the laminated film of the SiO₂ film 5 and the SiN film 7 is etched to form the open region 9. However, the etching paste residue 8a remains on the silicon surface. Therefore, after the open region 9 has been formed, the etching paste residue 8a is completely removed by a high-concentration alkaline solution and the texture 1T of the n-type silicon substrate 1 is processed. For example, as the high-concentration alkaline solution, an alkaline solution in which an etching rate of silicon is high as compared to the SiN film 7, such as potassium hydroxide (KOH), tetramethyl ammonia hydroxide (TMAH) can be used. Preferably, the etching temperature is from 40° C. to 100° C. inclusive in a range of the concentration of the etching solution used in the above process from 2% to 30% inclusive, and the etching time is from one minute to 30 minutes inclusive. As illustrated in FIG. 11(a), a surface processed portion 1F in the open region 9 where the texture 1T of the n-type silicon substrate 1 is processed is formed. As processing conditions, control by the etching time is possible. However, it is desired to perform processing so that optical reflectivity of the silicon substrate in a wavelength of 700 nanometers is 20% or higher. By setting the optical reflectivity to 20% or higher, visibility of the surface processed portion 1F increases as compared to other regions, and the surface processed portion 1F can be used as an alignment mark at the time of electrode formation, thereby facilitating alignment.

The dopant paste 10 is then applied to and diffused in the open region 9, to form a high-concentration n-type diffusion region, that is, an n⁺ layer as the high-concentration diffusion region 11. Because the open region 9 in the laminated film of the SiO₂ film 5 and the SiN film 7 is used instead of a mask, a mask having a fine pattern formed therein is not required at the time of performing screen printing. At this time, highly accurate alignment between the surface processed portion 1F and an opening of a screen printing mask can be realized, and thus an electrode can be selectively formed in the open region 9 easily. Other than this configuration, an electrode can be produced according to known techniques such as inkjet printing and spray printing; however, screen printing is more preferable in view of productivity. When an electrode is formed by using the inkjet or spray printing, a supply nozzle for sharing an electrode forming paste can be aligned with the surface processed portion 1F highly accurately, thereby enabling to improve pattern accuracy and workability. Because the laminated film of the SiO₂ film 5 and the SiN film 7 to be used as the passivation film and the open region 9 are used as a mask, as illustrated in FIG. 11(b), a region where the n⁺-type high-concentration diffusion region 11 is diffused on the n-type silicon substrate 1 is limited to the open region 9 opened by the etching paste 8.

The metal electrode 13 is then formed on the side of the light receiving surface 1A of the n-type silicon substrate 1 and bonded to the n⁺-type high-concentration diffusion region 11. Particularly, as the method for bonding the electrode with the high-concentration diffusion region 11, a conductive paste containing Ag is applied by screen printing. The conductive paste described above is applied to a region of the n⁺-type high-concentration diffusion region 11 on the n-type silicon substrate 1. In order to reduce the contact resistance between the high-concentration diffusion region 11 and the metal electrode 13, burning is performed. Although depending on the property of the conductive paste, burning is performed this time at a temperature of about 200° C. in a burning furnace. As illustrated in FIG. 11(c), an n-type solar cell is produced in the manner described above.

As described above, according to the present embodiment, by increasing the optical reflectivity of the surface processed portion 1F, visibility is improved further, and electrode formation in the open region 9 with high accuracy can be realized.

### Fourth Embodiment

In the example illustrated in FIG. 1, the pattern shapes of the open region 9 and the metal electrode 13 are the same except for the pattern width being different. However, in the fourth embodiment, the pattern shapes of the open region 9 and the metal electrode 13 are different. That is, in the open region 9, an open region is formed only in a grid electrode forming region arranged in parallel in a plurality of numbers, and any opening is not formed in a region having a wide width corresponding to a bus electrode that is orthogonal to the grid electrode forming region. The metal electrode 13 has a configuration including grid electrodes and bus electrodes having a wide width and orthogonal to the grid electrodes as in the first embodiment.

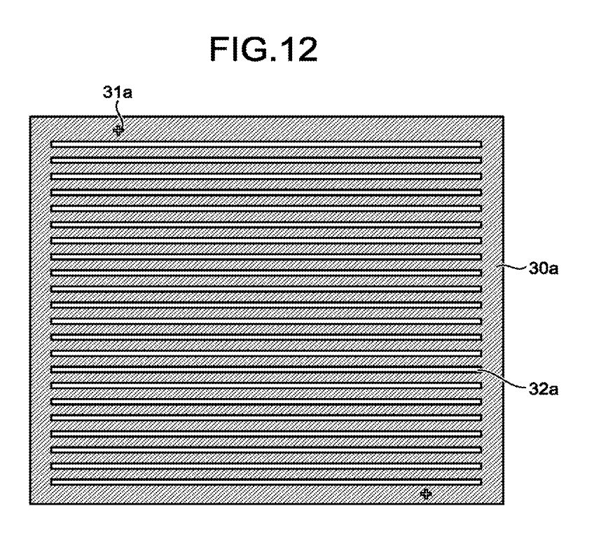

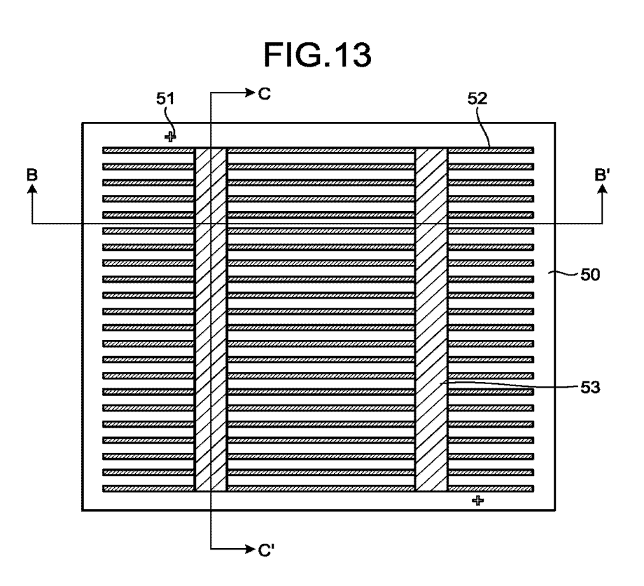

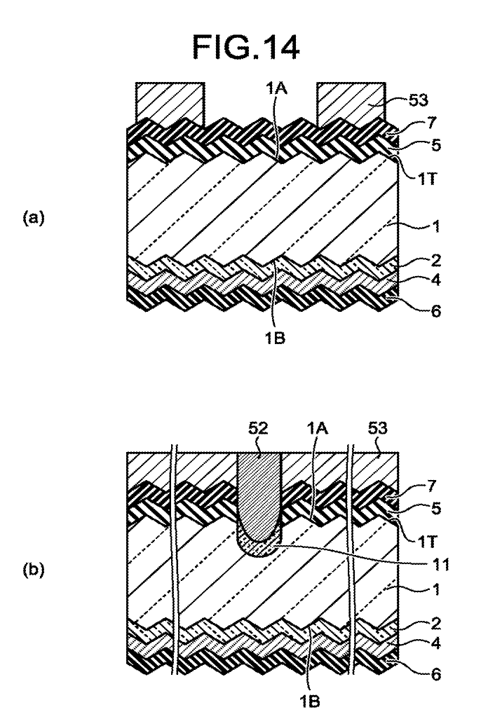

FIG. 12 is a plan view of an etching paste mask to be used in a manufacturing method for a solar cell according to the fourth embodiment. FIG. 13 is a plan view schematically illustrating a solar cell formed by the manufacturing method for a solar cell according to the fourth embodiment. FIG. 14(a) is a sectional view along a line B-B′ in FIG. 13, and FIG. 14(b) is a sectional view along a line C-C′ in FIG. 13. FIG. 14(b) illustrates a region in which only one grid electrode 52 can be put, and other elements are omitted; however, a plurality of grid electrodes 52 are arranged. In the solar cell of the fourth embodiment, the grid electrodes 52 and bus electrodes 53 are formed on an n-type silicon substrate 50, and an alignment mark 51 is formed at the upper left thereof.

According to the fourth embodiment, an opening is formed by using a mask shape for an etching paste illustrated in FIG. 12, and a metal electrode is formed by using a mask shape for forming a metal electrode illustrated in FIG. 5. In an etching paste mask 30a illustrated in FIG. 12, a plurality of opening patterns arranged in parallel at a regular interval are formed in the grid electrode forming region, and a cross-shaped opening that is an alignment mark 31a at an end portion thereof and a plurality of openings 32a for a grid electrode arranged in parallel are provided.

By forming the openings using the mask shape for an etching paste illustrated in FIG. 12, a pattern of a passivation film is formed in which openings are provided only in the grid electrode forming region and no opening is provided in a bus electrode forming region. By applying and diffusing a doping paste via the open region of the passivation film pattern, the high-concentration diffusion region 11 is formed. Also in this case, the open region of the passivation film consisting of the laminated film of the SiO₂ film 5 and the SiN film 7 is used instead of a mask. Therefore when screen printing is performed, a mask having a fine pattern formed therein is not required. The grid electrodes 52 and the bus electrodes 53 are formed in an upper layer thereof. In this manner, the bus electrodes 53 that are metal electrodes not connected to the high-concentration diffusion region 11 are formed in a part of the laminated film of the SiO₂ film 5 and the SiN film 7 as the passivation film. As illustrated in FIG. 14(a) and FIG. 14(b), the solar cell manufactured in this manner has a configuration in which a collecting electrode on the side of the light receiving surface 1A consists of the grid electrodes 52 and two bus electrodes 53 having a wide width and orthogonal to the grid electrodes 52. The bus electrodes 53 are formed on the SiN film 7 and do not abut on the high-concentration diffusion region 11.

As described above, according to the fourth embodiment, the grid electrodes 52 connected to each other via the high-concentration diffusion region 11 and the bus electrodes 53 intersecting the grid electrodes 52 are made of the same metal material. However, the bus electrodes 53 are formed on the SiN film 7, which is one component of the passivation film. That is, the solar cell and the manufacturing method therefor according to the fourth embodiment are different from those of the third embodiment in that the passivation film under the bus electrodes 53 is not opened, and the bus electrodes 53 do not come in contact with the high-concentration diffusion region 11 directly. The manufacturing process is the same as that of the first embodiment, except for a process of etching the surface prior to a change of a mask pattern and formation of the collecting electrode. Other processes are identical to those of the first embodiment, and thus descriptions thereof are omitted here. Constituent elements identical to those of the first embodiment are denoted by like reference signs.

According to such a configuration, high accuracy is realized by forming an opening in the etching paste mask only with respect to the grid electrodes 52 having a fine line width, which requires high pattern accuracy, and the bus electrodes 53 is caused not to come in contact with the high-concentration diffusion region 11 directly. Therefore, even when a laminated film of aluminum electrode and a silver electrode is used in order to reduce the cost of the bus electrode and improve current collecting performance, occurrence of interfacial reaction between silicon and metal can be prevented.

According to the present embodiment, even when the bus electrodes 53 having a large area is configured by a laminated film in which a first layer electrode consisting primarily of Al is arranged on a lower layer side and a second layer electrode consisting primarily of Ag is laminated on an upper layer of the first layer electrode, because the bus electrodes 53 do not come in contact with the high-concentration diffusion region 11, there is no possibility of occurrence of the interfacial reaction, thereby enabling to reduce current collecting resistance.

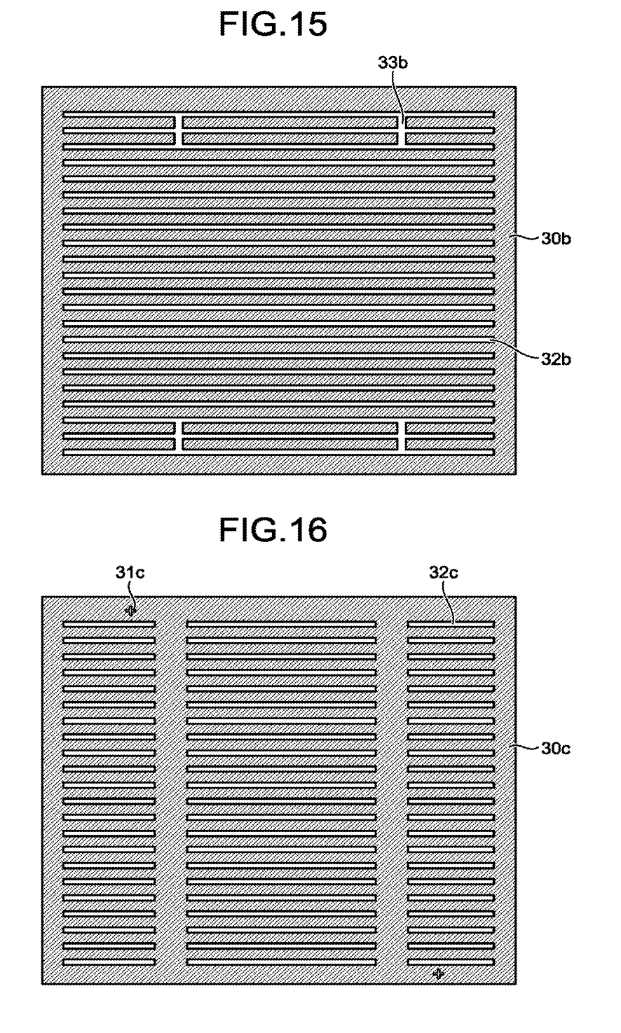

As a modification, as an etching paste mask 30b, as illustrated in FIG. 15, a mask in which an opening 33b for a bus electrode orthogonal to a grid electrode forming region is formed only in a part of a bus electrode forming region can be used. The etching paste mask 30b illustrated in FIG. 15 does not include an alignment mark at the end portion, but has a plurality of openings 32b for a grid electrode parallel to each other including cross-shaped openings 33b for a bus electrode in an element region. The opening 33b for a bus electrode is formed on each of four corners of the bus electrode forming region, that is, four openings 33b for a bus electrode are formed in total, thereby facilitating alignment. As compared to the etching paste mask 30a illustrated in FIG. 12, it is different only in that an alignment mark is not formed at the end portion, and a plurality of parallel openings 32b for a grid electrode and the openings 33b for a bus electrode orthogonal to the openings 32b for a grid electrode at four points thereon are formed. Accordingly, an effective region for current collection can be increased and a solar cell having a higher incident photoelectric conversion efficiency can be acquired.

### Fifth Embodiment

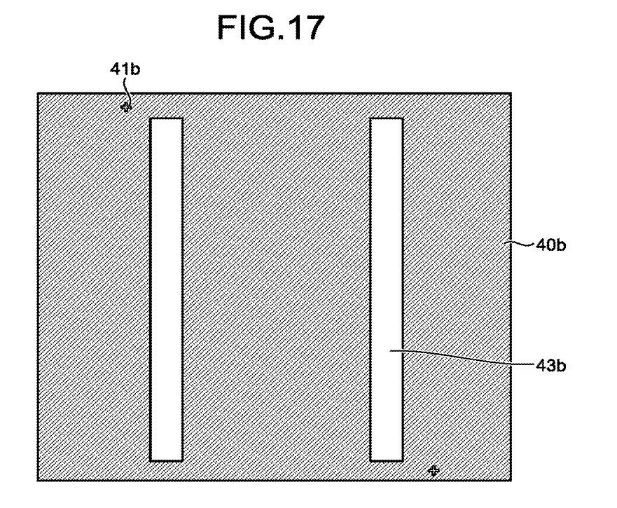

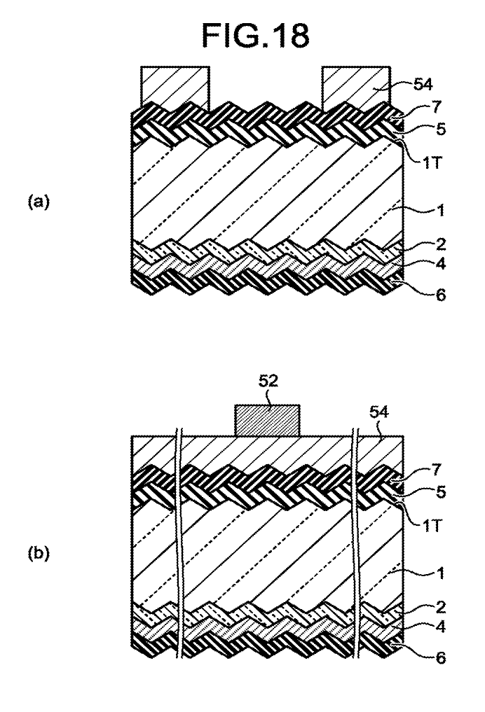

FIG. 16 is a plan view of an etching paste mask to be used in a manufacturing method for a solar cell according to a fifth embodiment, and FIG. 17 is a diagram illustrating a mask shape for forming a metal electrode according to the fifth embodiment. FIGS. 18(a) and 18(b) are diagrams schematically illustrating a solar cell formed by the manufacturing method for a solar cell according to the fifth embodiment, where FIG. 18(a) is a diagram corresponding to a sectional view along a line B-B′ in FIG. 13, and FIG. 18(b) is a diagram corresponding to a sectional view along a line C-C′ in FIG. 13.

In the first and fourth embodiments, the metal electrodes 13 or the grid electrodes 52 are formed on the side of the light receiving surface 1A of the n-type silicon substrate 1 and bonded to the n⁺-type high-concentration diffusion region 11. Particularly, as the method for bonding the metal electrodes 13 or the grid electrodes 52 to the n⁺-type high-concentration diffusion region 11, the conductive paste containing Ag is applied thereto by screen printing. However, for example, a mask 30c illustrated in FIG. 16 is used as a mask shape for an etching paste, and a combined mask of the mask 30a illustrated in FIG. 12 and a mask 40b illustrated in FIG. 17 can be used as a mask shape for forming a metal electrode. For example, the mask 30a illustrated in FIG. 12 is used for forming the grid electrodes, and the mask 40b illustrated in FIG. 17 is used for forming the bus electrodes. Alignment is performed by matching the pattern formed by the alignment mark 31a of the mask 30a with an alignment mark 31c of the mask 30c. Further, alignment is performed by matching the pattern formed by the alignment mark 31a of the mask 30a with an alignment mark 41b of the mask 40b.

A method for forming bus electrodes 54 consisting primarily of Al is described by using the mask 40b illustrated in FIG. 17. The plan view is the same as that of the solar cell of the fourth embodiment illustrated in FIG. 13. The solar cell is different from the solar cell of the fourth embodiment, as illustrated in FIGS. 18(a) and 18(b), in that the electrode on the side of the light receiving surface 1A is formed of the grid electrodes 52 formed of a metal electrode connected to each other via the high-concentration diffusion region and the bus electrodes 54 formed of an Al electrode formed on the SiN film 7, and that the high-concentration diffusion region is not formed immediately below a region where the grid electrodes 52 and the bus electrodes 54 intersect with each other. Other elements are identical to those of the first embodiment described above, and thus descriptions thereof are omitted here. Constituent elements identical to those of the first embodiment are denoted by like reference signs.

For example, the etching paste mask 30b illustrated in the plan view of FIG. 15 and the etching paste mask 40b illustrated in a plan view of FIG. 17 are combined. At this time, the openings 32b in the etching paste mask 30b and openings 43b for a bus electrode formed immediately below the bus electrodes orthogonal to the openings 32b are combined to form an electrode. In addition, as illustrated in FIG. 15, four intersecting openings configured by the openings 33b intersecting the openings 32b are formed, which can be used as alignment marks of the bus electrodes and the grid electrodes.

As described above, in the fifth embodiment, a process of forming an open region includes a process of forming a plurality of open regions parallel to a first direction on the surface of a first conductivity-type silicon substrate, a process of not making an opening in a second direction intersecting the open regions, a process of forming a high-concentration diffusion region by diffusing n-type impurities on the surface of the first conductivity-type silicon substrate in the opening, and a process of forming a collecting electrode in the high-concentration diffusion region of the open region and in a non-open region.

According to this configuration, the high-concentration diffusion region is caused not to be formed under an electrode intersecting portion such as an intersecting portion of the grid electrodes and the bus electrodes, which is a region having a large area, and the collecting electrode can be caused not to come in contact with the silicon substrate directly. Therefore, diffusion of the electrode material to the silicon substrate can be suppressed, thereby enabling to select a collecting-electrode forming material without any limitation.

Further, by forming a discontinuous portion in the process of forming the open region, the discontinuous portion can be used as an alignment mark, and thus it is not necessary to provide an alignment mark forming region separately. Consequently, an incident photoelectric conversion region can be used effectively.

### Sixth Embodiment

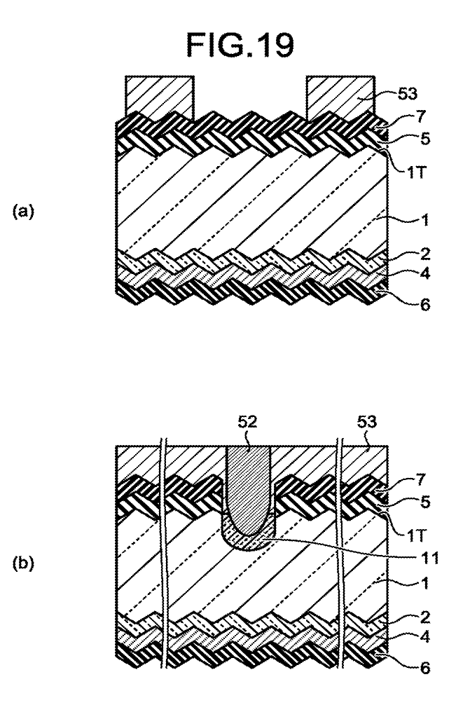

FIGS. 19(a) and 19(b) are diagrams schematically illustrating a solar cell manufactured by a manufacturing method for a solar cell according to a sixth embodiment, where FIG. 19(a) is a diagram corresponding to the sectional view along a line B-B′ in FIG. 13, and FIG. 19(b) is a diagram corresponding to the sectional view along a line C-C′ in FIG. 13. In FIG. 19(b), only one of a plurality of grid electrodes is illustrated, and other elements are omitted.

In the present embodiment, an opening is formed by using a mask shape for an etching paste identical to the mask 30a illustrated in FIG. 12. At this time, a different point from the fourth embodiment is that an opening in a portion corresponding to an intersecting region with bus electrodes is made large, so that a contact portion is formed large in the intersecting portion, and other elements are formed in a similar manner. Also in the present embodiment, the mask shape for forming a metal electrode illustrated in FIG. 5 is used.

In the solar cell formed according to the present embodiment, as compared to the solar cell formed according to the method of the fourth embodiment illustrated in FIG. 14(a) and FIG. 14(b), an opening having a wider width is formed in an intersecting region between the grid electrodes 52 and the two bus electrodes 53 with a wide width intersecting the grid electrodes 52, which form the collecting electrode on the side of the light receiving surface 1A. As in the fourth embodiment, the grid electrodes 52 are connected to the high-concentration diffusion region 11; however, a part of the bus electrode 53 also enters therein. In other parts, as in the solar cell of the fourth embodiment, the bus electrodes 53 are formed on the SiN film 7, which is one of the passivation film. That is, according to the solar cell and the manufacturing method therefor of the sixth embodiment, a different point from the manufacturing method for a solar cell of the fourth embodiment is that a part of the bus electrode 53 is formed by entering into the intersecting portion with the grid electrode 52 so as to come in contact with the high-concentration diffusion region 11 directly. The manufacturing process is the same as that of the first embodiment, except for a process of etching the surface prior to the change of the mask pattern and the formation of the collecting electrode. Other elements are identical to those of the first embodiment described above, and thus descriptions thereof are omitted here. Constituent elements identical to those of the first embodiment are denoted by like reference signs.

That is, the open region of the passivation film is formed along the grid electrodes 52 and in a larger width than the grid electrode width in the intersecting region between the bus electrodes 53 and the grid electrodes 52. Therefore, the bus electrode 53 enters from a gap between the open region and the grid electrode 52 and reaches the high-concentration diffusion region 11.

According to this configuration, because a part of metal constituting the bus electrode is formed by entering into the intersecting region with the grid electrode so as to come in contact with the high-concentration diffusion region 11 directly, the electrode is hardly peeled off. Other effects are identical to those of the first to fifth embodiments. In the case of the present embodiment, it is desired to use a silver electrode also for the bus electrode, in terms of preventing interfacial reaction between the substrate and the electrode.

As described above, by using the method of the first to sixth embodiments, the selective emitter structure can be formed without considerably increasing the man-hour, thereby enabling to achieve a high efficiency of the solar cell.

In the embodiments described above, the high-concentration diffusion region and the collecting electrode are formed and microfabrication thereof becomes possible, so that these embodiments are effective particularly on the light receiving surface side. However, because p-n separation can be easily performed and the high-concentration diffusion region and the collecting electrode can be formed without a margin, these embodiments are effective in formation of the n⁺-type high-concentration diffusion region in a back-surface extracting type solar cell. Further, the present invention can be applied not only to a bifacial solar cell but also to electrode extraction on the back surface side.

In any embodiment of the first to sixth embodiments, the present invention can be applied to a crystalline silicon substrate such as a monocrystalline silicon substrate and a polycrystalline silicon substrate, as the semiconductor substrate.

Further, in the first to sixth embodiments, an example including two bus electrodes has been described. However, it is needless to mention that the number of bus electrodes can be three or more, and a structure having a different configuration can be taken for each bus electrode, for example, by combining the configuration of the sixth embodiment with the configuration of the fifth embodiment.

While several embodiments of the present invention have been described above, these embodiments have been presented only as exemplarily embodiments of the invention and do not intend to limit the scope of the present invention. These novel embodiments can be realized in other various modes and various omissions, replacements, and modifications can be made without departing from the scope of the invention. These embodiments and modifications thereof are included within the scope of the invention, as well as within the inventions according to the claims and the range of equivalents thereof.

### REFERENCE SIGNS LIST

1 n-type silicon substrate, 1A light receiving surface, 1B back surface, 1F surface processed portion, 1T texture, 2 p-type diffusion region, 4 silicon oxide film, 5 silicon oxide film, 6 silicon nitride film, 7 silicon nitride film, 8 etching paste, 8a etching paste residue, 9 open region, 10 dopant paste, 11 high-concentration diffusion region, 12 metal electrode, 13 metal electrode, 14 mask, 15 opening for grid electrode, 16 opening for bus electrode, 17 alignment mark, 21 underlayer, 22 metal electrode, 23 metal electrode, 30a mask, 30b mask, 30c mask, 31a alignment mark, 31c alignment mark, 32a opening for grid electrode, 32b opening for grid electrode, 32c opening for grid electrode, 33b opening for bus electrode, 40b mask, 43b opening for bus electrode, 50 n-type silicon substrate, 51 alignment mark, 52 grid electrode, 53 bus electrode, 54 bus electrode.

1-17. (canceled)

18: A manufacturing method for a solar cell comprising:
a step of forming a second conductivity-type semiconductor region on one principal surface side of a first conductivity-type silicon substrate and forming a silicon substrate having a pn junction;
a step of forming a passivation film on a surface of a side of a first principal surface that is an n type, among the first principal surface and second principal surface of the silicon substrate;
a step of forming an open region in the passivation film by using an etching paste;
a step of diffusing n-type impurities with respect to the open region of the passivation film by using the passivation film as a mask to form a high-concentration diffusion region; and
a step of forming a collecting electrode selectively in the high-concentration diffusion region that is exposed in the open region of the passivation film, wherein
after the step of forming the open region, and before the step of forming the high-concentration diffusion region, the manufacturing method further comprises a step of etching a part of a surface of the silicon substrate by using the passivation film as a mask with respect to the open region of the passivation film, to form a concave portion having undergone texture machining, and
the step of forming the high-concentration diffusion region is a step of forming a high-concentration diffusion region extending with a constant thickness in a region on a surface constituting an n type among the first conductivity-type silicon substrate and the second conductivity-type semiconductor region, from the concave portion formed by the etching, and
the step of forming the collecting electrode is a step of forming the collecting electrode abutting on the concave portion on a surface of the high-concentration diffusion region.

19: The manufacturing method for a solar cell according to claim 18, wherein the step of forming an open region in the passivation film includes a step of applying an etching paste to a region where the open region is to be formed.

20: The manufacturing method for a solar cell according to claim 18, wherein
the silicon substrate is an n-type silicon substrate having first and second principal surfaces,
the second conductivity-type semiconductor region is a p-type diffusion region formed on a side of the second principal surface, and
the step of forming the high-concentration diffusion region is a step of forming a selective emitter region by selectively diffusing phosphorus on a side of the first principal surface as the n-type impurities.

21: The manufacturing method for a solar cell according to claim 20, wherein a concentration of phosphorus diffused in the open region of the passivation film is adjusted in a range from 1.0×10¹⁷/cm³ to 1.0×10²¹/cm³ inclusive.

22: The manufacturing method for a solar cell according to claim 18, wherein
the step of forming the selective emitter region includes
a step of applying a dopant paste to the open region of the passivation film using the passivation film as a mask, and
a step of heating the dopant paste.

23: The manufacturing method for a solar cell according to claim 18, wherein
the step of forming the collecting electrode includes
a step of forming a seed layer consisting of a metal film, and
a step of forming a plated layer on the seed layer.

24: The manufacturing method for a solar cell according to claim 23, wherein
the step of forming the seed layer is a step of forming a metal film consisting of Ni or Ti, and
the step of forming the plated layer includes a step of plating Ag or Cu on the seed layer.

25: The manufacturing method for a solar cell according to claim 18, wherein
the step of forming the open region includes
a step of forming a plurality of open regions in parallel to a first direction on the surface of the first conductivity-type silicon substrate,
a step of not making an opening in a second direction intersecting the open region,
a step of forming a high-concentration diffusion region by diffusing n-type impurities on the surface of the first conductivity-type silicon substrate in the open region, and
a step of forming a collecting electrode in the high-concentration diffusion region of the open region and a non-open region.

26: The manufacturing method for a solar cell according to claim 18, wherein the step of forming the open region is a step of forming an open region in which a shape of the open region that penetrates from a surface in a thickness direction parallel to a first direction on the passivation film and the surface of the first conductivity-type silicon substrate has a discontinuous portion in the first direction.

27: The manufacturing method for a solar cell according to claim 25, wherein the step of forming the collecting electrode includes a step of laminating a first layer electrode consisting primarily of Al on a lower layer side and a second layer electrode consisting primarily of Ag on an upper layer of the first layer electrode.

28: A solar cell comprising:
a first conductivity-type silicon substrate having first and second principal surfaces;
a second conductivity-type diffusion region formed on the first principal surface of the silicon substrate;
a passivation film that is formed on the first or second principal surface of the silicon substrate and has an open region;
a high-concentration diffusion region including n-type impurities selectively formed on a surface constituting an n type among the first conductivity-type silicon substrate and the second conductivity-type diffusion region, so as to coincide with the open region of the passivation film; and
a collecting electrode formed to abut on the high-concentration diffusion region so as to coincide with the open region of the passivation film, wherein
the high-concentration diffusion region extends from a concave portion having undergone texture machining in the open region, which is provided on a surface of the silicon substrate, to a region on the surface constituting an n type among the first conductivity-type silicon substrate and the second conductivity-type diffusion region, and
the collecting electrode abuts on the concave portion on a surface of the high-concentration diffusion region.

29: The solar cell according to claim 28, wherein
the collecting electrode is formed of
grid electrodes formed along the high-concentration diffusion region, and
bus electrodes intersecting the grid electrodes and connected to the grid electrodes, wherein the bus electrodes are formed on the passivation film so as not to come in contact with the high-concentration region.

30: The solar cell according to claim 29, wherein
the silicon substrate is an n-type silicon substrate having first and second principal surfaces,
the second conductivity-type diffusion region is a p-type diffusion region formed on a side of the second principal surface, and
the high-concentration diffusion region is a high-concentration diffusion region of phosphorus selectively formed on a side of the first principal surface that is a light-receiving surface.

31: The solar cell according to claim 30, wherein a concentration of phosphorus diffused in the open region of the passivation film is adjusted in a range from 1.0×10¹⁷/cm³ to 1.0×10²¹/cm³ inclusive.

32: The solar cell according to claim 29, wherein
the open region of the passivation film is formed along the grid electrode, and
has a larger width than that of the grid electrode in an intersecting region between the bus electrode and the grid electrode, and
the bus electrode reaches the high-concentration diffusion region from a gap between the passivation film surrounding the open region and the grid electrode.
